(19) United States
(12) Patent Application Publication
(10) Pub. No.: US 2026/0196791 A1
(43) Pub. Date: Jul. 9, 2026

(54) GAS LASER DEVICE AND ELECTRONIC DEVICE MANUFACTURING METHOD

(71) Applicant: Gigaphoton Inc., Oyama-shi (JP)

(72) Inventor: Kohei KUSAYANAGI, Oyama-shi (JP)

(73) Assignee: Gigaphoton Inc., Oyama-shi, Tochigi (JP)

(21) Appl. No.: 19/409,161

(22) Filed: Dec. 4, 2025

(30) Foreign Application Priority Data
Jan. 7, 2025 (JP) 2025-002532

(51) Int. Cl. H01S 3/00; G03F 7/00; H01S 3/034; H01S 3/1123; H01S 3/225

(52) U.S. Cl. CPC H01S 3/0057; G03F 7/70025; H01S 3/0071; H01S 3/034; H01S 3/1123; H01S 3/225

(57) ABSTRACT

A gas laser device includes a chamber device outputting pulse laser light, a pulse stretcher including looped optical paths, and a housing including a main body portion in which an opening is formed. Each of the looped optical paths includes a beam splitter, and a plurality of circulation mirrors sequentially reflecting a part of the pulse laser light incident on the beam splitter and returning the part of the pulse laser light to the beam splitter to be superimposed on another part thereof. The pulse stretcher includes a plurality of units each including two or more optical elements and being able to be individually taken in and out through the opening. The plurality of units includes first and second units. A deterioration speed of at least one optical element of the first unit is higher than a deterioration speed of the optical elements of the second unit.

### CROSS-REFERENCE TO RELATED APPLICATIONS

The present application claims the benefit of Japanese Patent Application No. 2025/002532, filed on Jan. 7, 2025, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

Since excimer laser light has a pulse width of about several 10 ns and a wavelength is short as 248 nm or 193 nm, excimer laser light is sometimes used for direct processing of a polymer material, a glass material, or the like. Chemical bonds in polymeric materials can be broken by excimer laser light having a photon energy higher than the bond energy. Therefore, it is known that non-heating processing of polymeric materials is possible with excimer laser light, and that the processing shape is beautiful. Further, it is known that, since glass, ceramics, and the like have high absorptance with respect to excimer laser light, even a material that is difficult to be processed with visible and infrared laser light can be processed with excimer laser light.

### LIST OF DOCUMENTS

### Patent Documents

Patent Document 1: Japanese Patent Application Publication No. 2005-148550

Patent Document 2: International Publication No. WO2024/047867

Patent Document 3: U.S. Pat. No. 9,093,817

### SUMMARY

A gas laser device according to an aspect of the present disclosure includes a chamber device configured to output pulse laser light, a pulse stretcher including a plurality of looped optical paths through which a pulse width of the pulse laser light is extended, and a housing including a main body portion in which the pulse stretcher is accommodated and an opening through which the pulse stretcher can be taken in and out is formed. Here, each of the looped optical paths includes a beam splitter on which the pulse laser light is incident, and a plurality of circulation mirrors configured to sequentially reflect a part of the pulse laser light incident on the beam splitter and return the part of the pulse laser light to the beam splitter so as to be superimposed on another part of the pulse laser light. The pulse stretcher includes a plurality of units each including two or more optical elements including at least one of the beam splitter and the circulation mirrors, and each being able to be individually taken in and out through the opening. The plurality of units includes a first unit and a second unit located on an opposite side of the opening with respect to the first unit. A deterioration speed of at least one of the optical elements of the first unit is higher than a deterioration speed of the optical elements of the second unit.

An electronic device manufacturing method according to an aspect of the present disclosure includes outputting pulse laser light generated by a gas laser device to an exposure apparatus, and exposing a photosensitive substrate in the exposure apparatus to the pulse laser light output to the exposure apparatus to manufacture an electronic device. Here, the gas laser device includes a chamber device configured to output the pulse laser light, a pulse stretcher including a plurality of looped optical paths through which a pulse width of the pulse laser light is extended, and a housing including a main body portion in which the pulse stretcher is accommodated and an opening through which the pulse stretcher can be taken in and out is formed. Each of the looped optical paths includes a beam splitter on which the pulse laser light is incident, and a plurality of circulation mirrors configured to sequentially reflect a part of the pulse laser light incident on the beam splitter and return the part of the pulse laser light to the beam splitter so as to be superimposed on another part of the pulse laser light. The pulse stretcher includes a plurality of units each including two or more optical elements including at least one of the beam splitter and the circulation mirrors, and each being able to be individually taken in and out through the opening. The plurality of units include a first unit and a second unit located on an opposite side of the opening with respect to the first unit. A deterioration speed of at least one of the optical elements of the first unit is higher than a deterioration speed of the optical elements of the second unit.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus used in an exposure process for an electronic device.

FIG. 2 is a schematic view showing a schematic configuration example of an entire gas laser device of a comparative example.

FIG. 3 is a schematic view of a schematic configuration example of a first light guide unit, a second light guide unit, and a pulse stretcher of the comparative example viewed obliquely from above.

FIG. 4 is a schematic view showing a schematic configuration example of a housing of the comparative example.

FIG. 5 is a schematic view of a schematic configuration example of the first light guide unit, the second light guide unit, and the pulse stretcher of a first embodiment viewed obliquely from above.

FIG. 6 is a schematic view showing a plurality of units and a housing of the first embodiment.

FIG. 7 is a schematic view showing a schematic configuration example of the unit of the first embodiment.

FIG. 8 is a schematic view of a schematic configuration example of the first light guide unit, the second light guide unit, and the pulse stretcher of a second embodiment viewed obliquely from above.

FIG. 9 is a schematic view showing the plurality of units and the housing of the second embodiment in a similar manner as in FIG. 6.

FIG. 10 is a schematic view showing the plurality of units and the housing of a first modification of the second embodiment in a similar manner as in FIG. 6.

FIG. 11 is a schematic view showing the plurality of units and the housing of a second modification of the second embodiment.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Maintenance method of pulse stretcher
   3.3 Effect
4. Description of gas laser device of second embodiment
   4.1 Configuration
   4.2 Maintenance method of pulse stretcher
   4.3 Effect
   4.4 Description of first modification
   4.5 Description of second modification

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

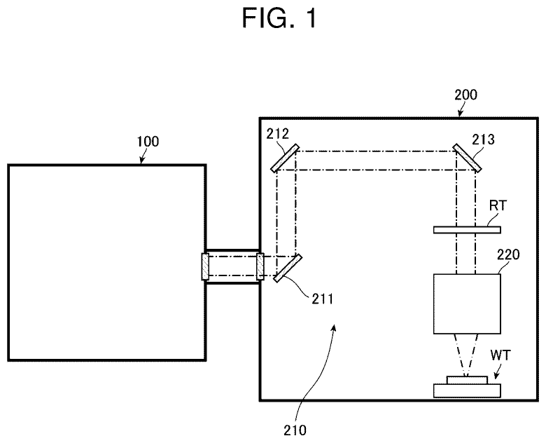

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

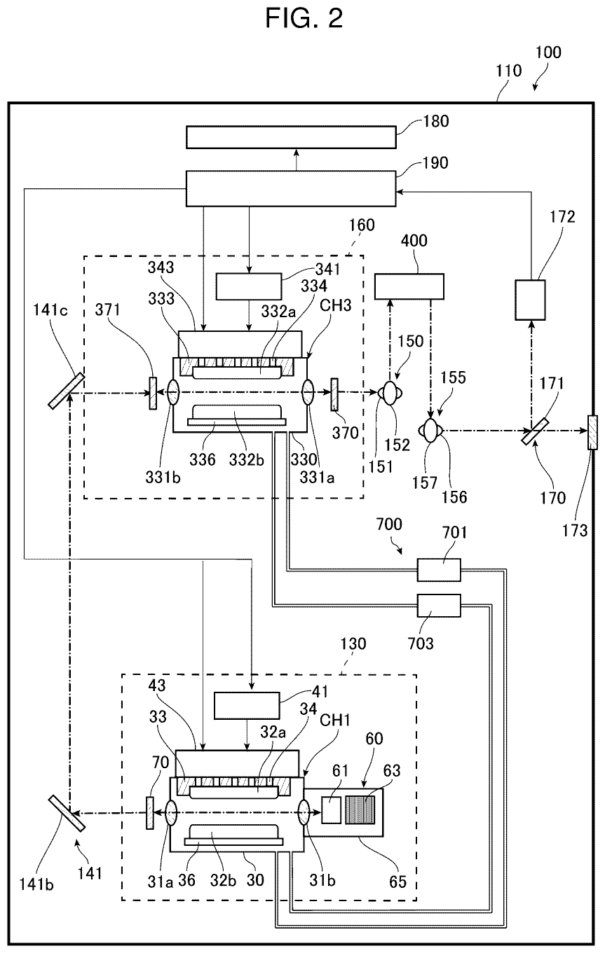

FIG. 2 is a schematic view showing a schematic configuration example of the entire gas laser device 100 of the comparative example. The gas laser device 100 is, for example, an ArF excimer laser device using a mixed gas including argon (Ar), fluorine (F₂), and neon (Ne). The gas laser device 100 outputs laser light having a center wavelength of about 193 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 includes a housing 110, and a laser oscillator 130 that is a master oscillator, an optical transmission unit 141, an amplifier 160 that is a power oscillator, a first light guide unit 150, a second light guide unit 155, a pulse stretcher 400, a detection unit 170, a display unit 180, a processor 190, and a gas module 700 arranged at an internal space of the housing 110 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from a laser gas supply device 703 of the gas module 700 to the internal space of the housing 30 via a pipe, and the laser gas is enclosed at the internal space. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are calcium fluoride substrates, and surfaces of the windows 31a, 31b on the inner side and the outer side of the housing 30 are flat surfaces. Here, the windows 31a, 31b are not limited to the calcium fluoride substrate as long as being capable of transmitting the laser light.

The electrodes 32a, 32b are arranged to face each other at the internal space of the housing 30, and the longitudinal direction of the electrodes 32a, 32b are along the travel direction of the light generated by the high voltage applied between the electrode 32a and the electrode 32b. The space between the electrode 32a and the electrode 32b in the housing 30 is sandwiched by the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30. Since a pulse high voltage is applied between the electrode 32a and the electrode 32b by the pulse power module 43 as described above, the laser light is pulse laser light.

The windows 31a, 31b may be inclined at the Brewster angle with respect to the travel direction of the laser light so that P-polarized light of the laser light is suppressed from being reflected. In the present example, the windows 31a, 31b are inclined with respect to a direction perpendicular to the travel direction of the laser light and a direction in which the electrodes 32a, 32b face each other. Therefore, the laser light output from the chamber device CH1 includes first linear polarization whose polarization direction is perpendicular to the direction in which the electrodes 32a, 32b face each other, and linear polarization whose polarization direction differs from the polarization direction of the first linear polarization is reduced from the laser light. That is, the windows 31a, 31b also serve as a polarizer that is inclined with respect to the polarization direction of the first linear polarization and reduces, from the laser light, the linear polarization whose polarization direction differs from the polarization direction of the first linear polarization.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 through the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 through the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator. Accordingly, the resonator causes the light to resonate between both sides sandwiching the chamber device CH1.

The optical transmission unit 141 includes high reflection mirrors 141b, 141c as a main configuration. The high reflection mirrors 141b, 141c are respectively fixed to holders (not shown) with inclination angles thereof adjusted, and are arranged at the internal space of the housing 110. The high reflection mirrors 141b, 141c highly reflects the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of windows 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. The direction in which the electrodes 332a, 332b face each other is a direction perpendicular to the polarization direction of the first linear polarization in the laser light from the laser oscillator 130.

The windows 331a, 331b may be inclined with respect to the polarization direction of the first linear polarization so that the first linear polarization in the laser light is incident thereon as P-polarized light and an incident angle θ of the laser light becomes the Brewster angle. Owing to the inclination of the windows 331a, 331b, the laser light output from the chamber device CH3 includes first linear polarization, and linear polarization whose polarization direction differs from the first linear polarization is reduced from the laser light. That is, similarly to the windows 31a, 31b, the windows 331a, 331b also serve as a polarizer that is inclined with respect to the polarization direction of the first linear polarization and reduce, from the laser light, the linear polarization whose polarization direction differs from the polarization direction of the first linear polarization. The outer shape of the laser light output from the windows 331a, 331b may be a rectangular shape elongated in a direction in which the pair of electrodes 332a, 332b face each other. Similarly to the pulse power module 43, the pulse power module 343 is a voltage application circuit.

The amplifier 160 is mainly different from the laser oscillator 130 in that the line narrowing module 60 is not included and a rear mirror 371 is included.

The rear mirror 371 is provided between the high reflection mirror 141c and the window 331b and faces to both thereof. The rear mirror 371 transmits a part of the laser light from the laser oscillator 130 toward the space between the electrodes 332a, 332b, and reflects a part of the laser light amplified by the electrodes 332a, 332b toward the space between the electrodes 332a, 332b.

The output coupling mirror 370 is provided between the window 331a and a high reflection mirror 151 and faces to both thereof. The output coupling mirror 370 reflects a part of the laser light amplified by the electrodes 332a, 332b and output toward the space between the electrodes 332a, 332b, and transmits another part of the laser light toward the high reflection mirror 151. For this purpose, the surface of the output coupling mirror 370 facing the window 331a is coated with a partial reflection film having a predetermined reflectance.

The output coupling mirror 370 may have a circular shape. A surface facing the window 331a and a surface opposite thereto of the output coupling mirror 370 are flat surfaces. The configuration of the output coupling mirror 370 is similar to that of the output coupling mirror 70.

The rear mirror 371 and the output coupling mirror 370 arranged with the housing 330 interposed therebetween configure a resonator in which the laser light amplified by the electrodes 332a, 332b resonates. The housing 330 is arranged on the optical path of the resonator. The laser light output from the window 331a of the housing 330 is incident on the output coupling mirror 370 and a part of the laser light is reflected by the output coupling mirror 370. The laser light reflected by the output coupling mirror 370 returns to the internal space of the housing 330 via the window 331a, and is output from the window 331b. The laser light output from the window 331b is reflected by the rear mirror 371 and returns to the internal space of the housing 330 through the window 331b. Thus, the laser light output from the housing 330 reciprocates between the rear mirror 371 and the output coupling mirror 370. The reciprocating laser light is amplified every time the laser light passes through a discharge space between the electrode 332a and the electrode 332b. That is, the resonator resonates light between both sides sandwiching the chamber device CH3, and the output coupling mirror 370 is arranged on one side of sandwiching the chamber device CH3. A part of the amplified laser light is transmitted through the output coupling mirror 370. The laser light transmitted through the output coupling mirror 370 travels to the high reflection mirror 151. As described above, the laser light traveling from the output coupling mirror 370 to the high reflection mirror 151 is pulse laser light.

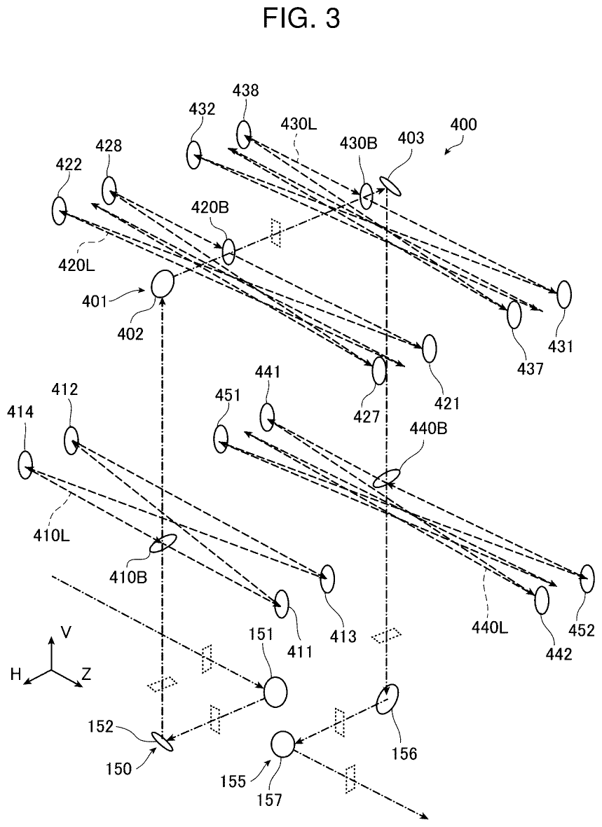

FIG. 3 is a schematic view of a schematic configuration example of the first light guide unit 150, the second light guide unit 155, and the pulse stretcher 400 of the comparative example viewed obliquely from above. The first light guide unit 150 includes high reflection mirrors 151, 152 as a main configuration. In the following, a direction in which the laser light propagates and which is parallel to the optical axis direction of the laser light output from the window 331a of the chamber device CH3 and transmitted through the output coupling mirror 370 is described as a Z direction, a height direction of the gas laser device 100 is described as a V direction, and a direction perpendicular to the V direction and the Z direction is described as an H direction. In the present example, the optical axis direction of the laser light output from the window 331a and transmitted through the output coupling mirror 370 is substantially parallel to the horizontal direction. Here, the V direction of the present example is parallel to the gravity direction.

The high reflection mirrors 151, 152 are respectively fixed to holders (not shown) with inclination angles thereof adjusted, and highly reflect the laser light. In FIG. 3, the outer shape of the laser light is indicated by a dotted line. The high reflection mirrors 151, 152 are, for example, planar mirrors. The high reflection mirror 151 is arranged on the optical path of the laser light from the output coupling mirror 370, and reflects the laser light in the H direction. The high reflection mirror 152 is arranged on the optical path of the laser light reflected by the high reflection mirror 151, and reflects the laser light in the V direction. The laser light reflected by the high reflection mirror 152 enters the pulse stretcher 400.

The pulse stretcher 400 includes a plurality of optical elements, extends the pulse width of the laser light having entered the pulse stretcher 400 from the first light guide unit 150, and outputs the laser light whose pulse width has been extended toward the second light guide unit 155.

The pulse stretcher 400 of the present example includes a light guide optical system 401 and four looped optical paths 410L, 420L, 430L, 440L as a main configuration, and is arranged on the V direction side with respect to the optical axis of the laser light transmitted through the output coupling mirror 370.

The light guide optical system 401 of the present example includes two light guide mirrors 402, 403 which are optical elements as a main configuration. The light guide mirrors 402, 403 are respectively fixed to holders (not shown) with inclination angles thereof adjusted, and highly reflect the laser light. The light guide mirrors 402, 403 are, for example, planar mirrors. The light guide mirror 402 is located on the H direction side with respect to the optical axis of the laser light transmitted through the output coupling mirror 370, and is arranged on the optical path of the laser light reflected by the high reflection mirror 152. The light guide mirror 402 reflects the laser light reflected by the high reflection mirror 152 in the −H direction. The light guide mirror 403 is arranged on the optical path of the laser light reflected by the light guide mirror 402 and on the −H direction side with respect to the optical axis of the laser light transmitted through the output coupling mirror 370. The light guide mirror 403 reflects the laser light reflected by the light guide mirror 402 in the −V direction, and the laser light is output from the pulse stretcher 400.

The looped optical path 410L of the present example is formed by a beam splitter 410B which is an optical element and four circulation mirrors 411, 412, 413, 414 being separate optical elements. The beam splitter 410B is arranged on the optical path of the laser light having been reflected by the high reflection mirror 152, having entered the pulse stretcher 400, and traveling toward the light guide mirror 402 among the optical paths of the laser light in the light guide optical system 401, and is fixed by a holder (not shown). The beam splitter 410B separates the incident laser light into two beams, transmits one separated beam toward the light guide mirror 402 to cause the one separated beam to propagate on the optical path of the light guide optical system 401, and reflects the other separated beam toward the circulation mirror 411.

The circulation mirrors 411 to 414 are, for example, concave mirrors, and are respectively supported by holders (not shown). The circulation mirrors 411, 413 are arranged on the Z direction side with respect to the light guide mirrors 402, 403 and are aligned in the −H direction in the order of the circulation mirrors 411, 413. The circulation mirrors 412, 414 are arranged on the −Z direction side with respect to the light guide mirrors 402, 403 and are aligned in the H direction in the order of the circulation mirrors 412, 414. The circulation mirror 411 and the circulation mirror 414, and the circulation mirror 412 and the circulation mirror 413 face each other in a direction parallel to the Z direction. The beam splitter 410B is located between the circulation mirror 411 and the circulation mirror 414.

The circulation mirrors 411 to 414 sequentially reflect the laser light reflected by the beam splitter 410B in the order of the circulation mirrors 411, 412, 413, 414, and return the laser light to the beam splitter 410B. The laser light reflected by the circulation mirror 414 is incident on the beam splitter 410B from a surface opposite to a surface on which the laser light reflected by the high reflection mirror 152 is incident. Thus, the looped optical path 410L, which is an optical path of the laser light returning from the beam splitter 410B to the beam splitter 410B via the circulation mirrors 411 to 414, is formed, and the looped optical path 410L spreads in the H direction and the Z direction.

The beam splitter 410B reflects a part of the laser light reflected by the circulation mirror 414 and returned to the beam splitter 410B toward the light guide mirror 402, and transmits another part toward the circulation mirror 411. The transmitted laser light propagates through the looped optical path 410L. Thus, the laser light is reflected four times in the looped optical path 410L to make one turn thereof, and circulates on the looped optical path 410L to make one or more turns.

The laser light returning to the beam splitter 410B after making one turn of the looped optical path 410L, separated by the beam splitter 410B, and traveling toward the light guide mirror 402 travels from the beam splitter 410B toward the light guide mirror 402 as being delayed by a predetermined time period as compared with the laser light traveling toward the light guide mirror 402 as being transmitted through the beam splitter 410B without traveling to the circulation mirror 411. The laser light traveling from the beam splitter 410B toward the light guide mirror 402 delayed by the predetermined time period overlaps a part of the laser light traveling toward the light guide mirror 402 as being transmitted through the beam splitter 410B without traveling to the circulation mirror 411. That is, the laser light returning to the beam splitter 410B is separated into laser light to overlap a part of one of the beams of the laser light having separated by the beam splitter 410B and laser light to be reflected sequentially by the circulation mirrors 411 to 414. The overlapping of the laser light occurs every time the laser light makes one turn of the looped optical path 410L, and the laser light having the pulse width extended by the overlapping of the laser light travels toward the light guide mirror 402 and propagates through the light guide optical system 401.

The looped optical path 420L of the present example includes a beam splitter 420B which is an optical element and eight circulation mirrors 421 to 428 being separate optical elements. In FIG. 3, for easy viewing, only four circulation mirrors 421, 422, 427, 428 are shown, and four circulation mirrors 423 to 426 are omitted. The beam splitter 420B is arranged on the optical path of the laser light having been reflected by the light guide mirror 402, and traveling toward the light guide mirror 403 among the optical paths of the laser light in the light guide optical system 401, and is fixed by a holder (not shown). The circulation mirrors 421 to 428 are, for example, concave mirrors, and are respectively supported by holders (not shown). The circulation mirrors 421, 423, 425, 427 are arranged on the Z direction side with respect to the light guide mirrors 402, 403, and the circulation mirrors 422, 424, 426, 428 are arranged on the −Z direction side with respect to the light guide mirrors 402, 403. Similarly to the circulation mirrors 411 to 414 of the looped optical path 410L, the circulation mirrors 421 to 428 sequentially reflect a part of the laser light incident on the beam splitter 420B in the order of the circulation mirrors 421 to 428, and return the part of the laser light to the beam splitter 420B so as to be superimposed on another part of the laser light. Then, similarly to the looped optical path 410L, superimposition of the laser light occurs, and the laser light having the pulse width extended travels from the beam splitter 420B toward the light guide mirror 403 and propagates through the light guide optical system 401. The looped optical path 420L spreads in the H direction and the Z direction. The optical path length of the looped optical path 420L is longer than the optical path length of the looped optical path 410L. Further, the looped optical path 420L is located on the V direction side with respect to the looped optical path 410L, and the looped optical path 410L and the looped optical path 420L overlap each other in a direction parallel to the V direction.

The looped optical path 430L of the present example includes a beam splitter 430B which is an optical element and eight circulation mirrors 431 to 438 being separate optical elements. In FIG. 3, for easy viewing, only four circulation mirrors 431, 432, 437, 438 are shown, and four circulation mirrors 433 to 436 are omitted. The beam splitter 430B is arranged on the optical path of the laser light traveling from the beam splitter 420B toward the light guide mirror 403 among the optical paths of the laser light in the light guide optical system 401, and is fixed by a holder (not shown). The circulation mirrors 431 to 438 are, for example, concave mirrors, and are respectively supported by holders (not shown). The circulation mirrors 431, 433, 435, 437 are arranged on the Z direction side with respect to the light guide mirrors 402, 403, and the circulation mirrors 432, 434, 436, 438 are arranged on the −Z direction side with respect to the light guide mirrors 402, 403. Similarly to the circulation mirrors 411 to 414 of the looped optical path 410L, the circulation mirrors 431 to 438 sequentially reflect a part of the laser light incident on the beam splitter 430B in the order of the circulation mirrors 431 to 438, and return the part of the laser light to the beam splitter 430B so as to be superimposed on another part of the laser light. Then, similarly to the looped optical path 410L, superimposition of the laser light occurs, and the laser light having the pulse width extended travels from the beam splitter 430B toward the light guide mirror 403 and propagates through the light guide optical system 401. The looped optical path 430L spreads in the H direction and the Z direction. The optical path length of the looped optical path 430L is longer than the optical path length of the looped optical path 410L and is substantially the same as the optical path length of the looped optical path 420L. Further, the looped optical path 430L is located on the −H direction side with respect to the looped optical path 420L, and the looped optical path 420L and the looped optical path 430L overlap each other in a direction parallel to the H direction.

The looped optical path 440L of the present example includes a beam splitter 440B which is an optical element and twelve circulation mirrors 441 to 452 being separate optical elements. In FIG. 3, for easy viewing, only four circulation mirrors 441, 442, 451, 452 are shown, and eight circulation mirrors 443 to 450 are omitted. The beam splitter 440B is arranged on the optical path of the laser light reflected by the light guide mirror 403 in the −V direction among the optical paths of the laser light in the light guide optical system 401, and is fixed by a holder (not shown). The beam splitter 440B separates the incident laser light into two beams, transmits one separated beam so as to be output from the pulse stretcher 400 and travel toward the second light guide unit 155, and reflects the other separated beam toward the circulation mirror 441.

The circulation mirrors 441 to 452 are, for example, concave mirrors, and are respectively supported by holders (not shown). The circulation mirrors 441, 443, 445, 447 are arranged on the Z direction side with respect to the light guide mirrors 402, 403, and the circulation mirrors 442, 444, 446, 448, 450, 452 are arranged on the −Z direction side with respect to the light guide mirrors 402, 403. Similarly to the circulation mirrors 411 to 414 of the looped optical path 410L, the circulation mirrors 441 to 452 sequentially reflect a part of the laser light incident on the beam splitter 440B in the order of the circulation mirrors 441 to 452, and return the part of the laser light to the beam splitter 440B so as to be superimposed on another part of the laser light. Then, similarly to the looped optical path 410L, superimposition of the laser light occurs, and the laser light having the pulse width extended propagates through the light guide optical system 401 toward the second light guide unit 155. The looped optical path 440L spreads in the H direction and the Z direction. The optical path length of the looped optical path 440L is longer than the optical path length of each of the looped optical paths 410L, 420L, 430L. The looped optical path 440L is located on the −V direction side with respect to the looped optical path 430L and on the −H direction side with respect to the looped optical path 410L. The looped optical path 430L and the looped optical path 440L overlap each other in a direction parallel to the V direction, and the looped optical path 410L and the looped optical path 440L overlap each other in a direction parallel to the H direction.

Thus, the light guide optical system 401 causes the laser light to be sequentially incident on the beam splitters 410B to 440B of the looped optical paths 410L to 440L. The optical path formed by the light guide optical system 401 is a non-looped optical path. Then, the pulse width of the laser light is sequentially extended by the looped optical paths 410L to 440L. That is, the looped optical paths 410L, 420L, 430L, 440L are arranged in this order from the upstream side to the downstream side in the travel direction of the laser light. Then, the laser light whose pulse width has been extended is output from the pulse stretcher 400, and the laser light travels to the second light guide unit 155.

The second light guide unit 155 of the present example mainly includes high reflection mirrors 156, 157 as a main configuration. The high reflection mirrors 156, 157 are respectively fixed to holders (not shown) with inclination angles thereof adjusted, and highly reflects the laser light. The high reflection mirrors 156, 157 are, for example, planar mirrors. The high reflection mirror 156 is arranged on the optical path of the laser light output from the pulse stretcher 400, and is located on the −H direction side with respect to the optical axis of the laser light transmitted through the output coupling mirror 370. The high reflection mirror 156 reflects the laser light output from the pulse stretcher 400 in the H direction. The high reflection mirror 157 is arranged on the optical path of the laser light reflected by the high reflection mirror 156, and the high reflection mirror 157 and the high reflection mirror 151 are aligned in the V direction. The high reflection mirror 157 reflects, in the Z direction, the laser light reflected by the high reflection mirror 156. The optical axis of the laser light traveling from the high reflection mirror 157 to the detection unit 170 may be non-parallel to the optical axis of the laser light transmitted through the output coupling mirror 370.

The detection unit 170 includes a beam splitter 171 and an optical sensor 172 as a main configuration.

The beam splitter 171 is arranged on the optical path of the laser light output from the second light guide unit 155. The beam splitter 171 transmits the laser light output from the second light guide unit 155 toward an output window 173 at a high transmittance, and reflects a part of the laser light toward a light receiving surface of the optical sensor 172.

The optical sensor 172 measures a pulse energy of the laser light incident on the light receiving surface of the optical sensor 172. The optical sensor 172 is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided in a wall of the housing 110. The light transmitted through the beam splitter 171 is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The gas module 700 includes a laser gas exhaust device 701 and a laser gas supply device 703. The laser gas exhaust device 701 and the laser gas supply device 703 are electrically connected to the processor 190 with signal lines (not shown). The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

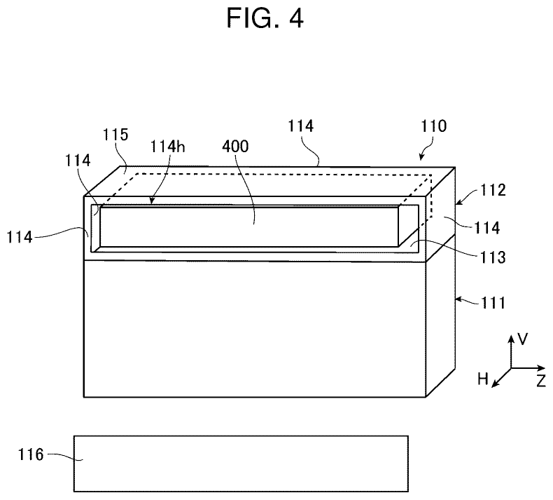

FIG. 4 is a schematic view showing a schematic configuration example of the housing 110 of the comparative example. As shown in FIG. 4, the housing 110 of the present example includes a first main body portion 111, a second main body portion 112, and a maintenance panel 116 as a main configuration. The first main body portion 111 is a box-shaped member having a space therein, and various devices such as the laser oscillator 130 and the amplifier 160 described above are accommodated at the internal space. In the present example, the shape of the first main body portion 111 is a rectangular parallelepiped shape elongated in the Z direction, and the first main body portion 111 includes four side walls, a lower wall, and an upper wall.

The second main body portion 112 is a box-shaped member having a space therein, and the pulse stretcher 400 is accommodated at the internal space. In the present example, the shape of the second main body portion 112 is a rectangular parallelepiped shape elongated in the Z direction, and the second main body portion 112 is arranged on the upper wall of the first main body portion 111. The second main body portion 112 includes a rectangular lower wall 113 elongated in the Z direction, four rectangular side walls 114 connected to four sides of the lower wall 113 respectively, and a rectangular upper wall 115 faced to the lower wall 113 and connected to the side walls 114. Two side walls 114 face each other in a direction parallel to the Z direction and are parallel to the H direction and the V direction. The other two side walls 114 face each other in a direction parallel to the H direction and are parallel to the Z direction and the V direction. Among the two side walls 114 facing each other in a direction parallel to the H direction, an opening 114h is formed in the side wall 114 located on the H direction side, and the pulse stretcher 400 accommodated at the internal space is accessible through the opening 114h. The outline outer shape of the opening 114h is a rectangular shape elongated in the Z direction, and the opening direction of the opening 114h is the H direction, which is the horizontal direction.

The maintenance panel 116 is a plate-shaped member that closes the opening 114h. The maintenance panel 116 is detachably attached to the second main body portion 112. FIG. 4 shows a state in which the maintenance panel 116 is removed from the second main body portion 112. Here, the opening 114h is only required to allow the pulse stretcher 400 to be taken in and out therethrough, and the position, shape, and the like of the opening 114h are not limited.

As described above, the laser light reflected by the high reflection mirror 152 in the V direction enters the pulse stretcher 400, and the laser light reflected by the light guide mirror 403 in the −V direction is output from the pulse stretcher 400. Therefore, the upper wall of the first main body portion 111 and the lower wall 113 of the second main body portion 112 are provided with a through hole (not shown) through which the laser light reflected by the high reflection mirror 152 in the V direction passes and another through hole (not shown) through which the laser light reflected by the light guide mirror 403 in the −V direction passes.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

Before the gas laser device 100 outputs the laser light, the processor 190 receives a signal indicating a target energy Et and a signal indicating a light emission trigger from the exposure processor. The target energy Et is a target value of the energy of the laser light to be used in the exposure process. The processor 190 sets a predetermined charge voltage to the charger 41 so that the energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. The laser light includes the first linear polarization, and linear polarization whose polarization direction differs from the first linear polarization is reduced from the laser light transmitted through the windows 31a, 31b. A part of the laser light is transmitted through the output coupling mirror 70, is reflected by the high reflection mirrors 141b, 141c, is transmitted through the rear mirror 371 and the window 331b, and travels into the housing 330.

The processor 190 turns ON the switch of the pulse power module 343 so that discharge occurs between the electrodes 332a, 332b when the laser light from the laser oscillator 130 travels to the discharge space in the housing 330. That is, the processor 190 controls the pulse power module 343 such that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light traveling to the internal space of the housing 330 is transmitted through the windows 331a, 331b as described above and travels to the rear mirror 371 and the output coupling mirror 370. Thus, the laser light having a predetermined wavelength reciprocates between the rear mirror 371 and the output coupling mirror 370. The laser light includes the first linear polarization, and linear polarization whose polarization direction differs from the first linear polarization is reduced from the laser light transmitted through the windows 331a, 331b. Further, the laser light is amplified every time passing through the discharge space at the internal space of the housing 330, and a part of the laser light becomes amplified laser light.

The amplified laser light from the amplifier 160 is transmitted through the output coupling mirror 370 and travels to the high reflection mirror 151. The laser light is reflected by the high reflection mirror 151 toward the high reflection mirror 152. The laser light reflected by the high reflection mirror 151 is reflected by the high reflection mirror 152 in the V direction and enters the pulse stretcher 400.

The laser light entering the pulse stretcher 400 is reflected by the light guide mirror 402 in the −H direction and travels to the light guide mirror 403. The laser light is reflected by the light guide mirror 403 in the −V direction and is output from the pulse stretcher 400. Further, in the pulse stretcher 400, the pulse width of the laser light is extended by each of the looped optical paths 410L to 440L in the course of being sequentially reflected by the light guide mirrors 402, 403 of the light guide optical system as described above. Then, the laser light whose pulse width has been extended is output from the pulse stretcher 400, and travels to the high reflection mirror 156. The laser light is reflected by the high reflection mirror 156 toward the high reflection mirror 157. The laser light reflected by the high reflection mirror 156 is reflected by the high reflection mirror 157 in the Z direction and travels to the beam splitter 171.

A part of the laser light having traveled to the beam splitter 171 is transmitted through the beam splitter 171 and the output window 173 and travels to the exposure apparatus 200, while another part is reflected by the beam splitter 171 and travels to the optical sensor 172.

The optical sensor 172 measures the energy E of the received laser light. The optical sensor 172 outputs a signal indicating the measured energy E to the processor 190. The processor 190 performs feedback control on the charge voltages of the chargers 41, 341 so that a difference ΔE between the energy E and the target energy Et is within an allowable range.

### 2.3 Problem

The pulse stretcher 400 includes the beam splitters 410B to 440B, the circulation mirrors 411 to 414, 421 to 428, 431 to 438, 441 to 452, and the light guide mirrors 402, 403, which are optical elements, and includes four looped optical paths 410L to 440L. The optical elements need to be replaced as being deteriorated. For example, in each of the looped optical paths 410L to 440L, the deterioration speed of the beam splitters 410B to 440B is higher than that of the circulation mirrors 411 to 414, 421 to 428, 431 to 438, 441 to 452. This is because the beam splitters 410B to 440B repeat transmission and reflection of the laser light. Further, in the travel direction of the laser light, the optical elements arranged on the upstream side tend to deteriorate more easily. This is because the pulse width of the laser light at the upstream side is shorter than the pulse width of the laser light at the downstream side, and the intensity of the laser light at the upstream side is higher than the intensity of the laser light at the downstream side. As described above, the deterioration speed varies depending on the type and arrangement of the optical elements, and the replacement frequency of optical elements having a high deterioration speed is high. As described above, there is a demand for facilitating the replacement of optical elements having a high replacement frequency and facilitating maintenance.

Therefore, in the following embodiments, a gas laser device capable of easily performing maintenance is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed.

### 3.1 Configuration

The pulse stretcher 400 of the present embodiment is different from the pulse stretcher 400 of the comparative example mainly in including a plurality of units each including two or more optical elements including at least one of a beam splitter and a mirror among the beam splitters 410B to 440B, the circulation mirrors 411 to 414, 421 to 428, 431 to 438, 441 to 452, and the light guide mirrors 402, 403.

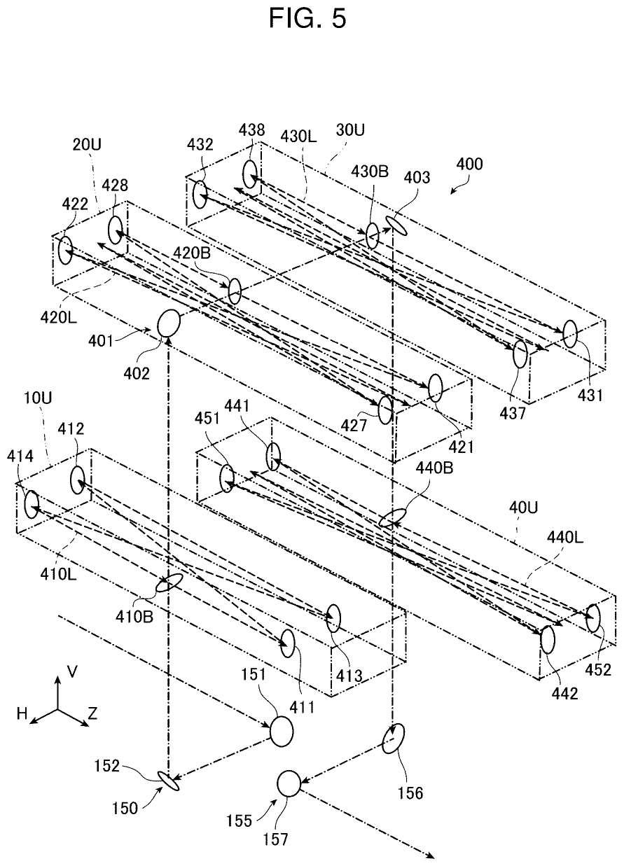

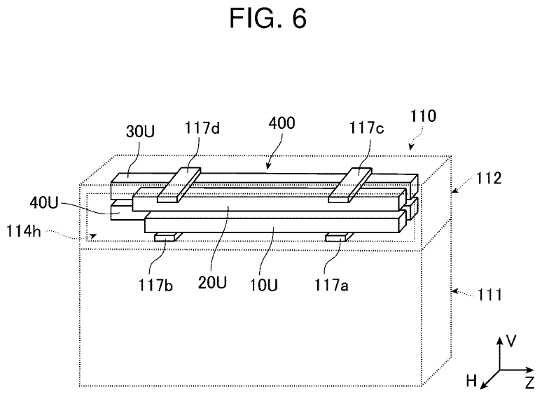

FIG. 5 is a schematic view of a schematic configuration example of the first light guide unit 150, the second light guide unit 155, and the pulse stretcher 400 of the present embodiment viewed obliquely from above. FIG. 6 is a schematic view showing the plurality of units and the housing 110 of the first embodiment. In FIG. 6, the first main body portion 111 and the second main body portion 112 of the housing 110 are indicated by dotted lines, and the maintenance panel 116 is omitted. As shown in FIGS. 5 and 6, in the present embodiment, units are formed respectively for the looped optical paths 410L to 440L, and the pulse stretcher 400 includes four units 10U, 20U, 30U, 40U. The unit 10U includes the looped optical path 410L, the unit 20U includes the looped optical path 420L, the unit 30U includes the looped optical path 430L, and the unit 40U includes the looped optical path 440L. The units 10U to 40U can be individually taken in and out through the opening 114h of the second main body portion 112. Further, the second main body portion 112 includes four movement mechanisms 117a to 117d. In FIG. 6, the second main body portion 112 is indicated by dotted lines.

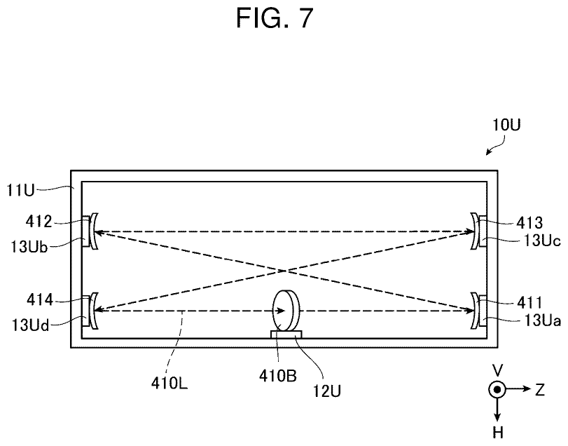

FIG. 7 is a schematic view showing a schematic configuration example of the unit 10U of the first embodiment. As shown in FIG. 7, the unit 10U includes the beam splitter 410B and the circulation mirrors 411 to 414, which are optical elements configuring the looped optical path 410L, and a frame 11U as a main configuration. Therefore, the number of optical elements included in the unit 10U is five.

The frame 11U is a member that supports the beam splitter 410B and the circulation mirrors 411 to 414. The frame 11U of the present embodiment is a frame-shaped member having a rectangular outer shape and surrounding the beam splitter 410B and the circulation mirrors 411 to 414. The beam splitter 410B is fixed to a holder 12U fixed to the frame 11U with the inclination angle thereof adjusted. The circulation mirrors 411 to 414 are respectively fixed to holders 13Ua to 13Ud fixed to the frame 11U with the inclination angle thereof adjusted. Thus, the beam splitter 410B and the circulation mirrors 411 to 414 are supported by the frame 11U. Here, the frame 11U is only required to support the beam splitter 410B and the circulation mirrors 411 to 414, and is not limited to the above. For example, when the optical path of the laser light and the frame 11U intersect each other, a through hole through which the laser light passes may be formed in the frame 11U.

Although not shown, the unit 20U includes the beam splitter 420B and the circulation mirrors 421 to 428, which are optical elements configuring the looped optical path 420L, and a frame (not shown) as a main configuration. Therefore, the number of optical elements included in the unit 20U is nine. The configuration of the frame of the unit 20U is similar to that of the frame 11U of the unit 10U. The beam splitter 420B and the circulation mirrors 421 to 428 are supported by the frame with the inclination angles thereof adjusted in a similar manner as the beam splitter 410B and the circulation mirrors 411 to 414.

Further, the unit 30U includes the beam splitter 430B and the circulation mirrors 431 to 438, which are optical elements configuring the looped optical path 430L, and a frame (not shown) as a main configuration. Therefore, the number of optical elements included in the unit 30U is nine. The configuration of the frame of the unit 30U is similar to that of the frame 11U of the unit 10U. The beam splitter 430B and the circulation mirrors 431 to 438 are supported by the frame with the inclination angles thereof adjusted.

Further, the unit 40U includes the beam splitter 440B and the circulation mirrors 441 to 452, which are optical elements configuring the looped optical path 440L, and a frame (not shown) as a main configuration. Therefore, the number of optical elements included in the unit 40U is thirteen. The configuration of the frame of the unit 40U is similar to that of the frame 11U of the unit 10U. The beam splitter 440B and the circulation mirrors 441 to 452 are supported by the frame with the inclination angles thereof adjusted.

As described above, the looped optical path 440L is located on the −H direction side with respect to the looped optical path 410L, and the looped optical path 410L and the looped optical path 440L overlap each other in a direction parallel to the H direction. Therefore, as shown in FIG. 6, the unit 10U is located on the opening 114h side with respect to the unit 40U, and the unit 10U and the unit 40U overlap each other in a direction parallel to the opening direction of the opening 114h. The unit 10U is arranged upstream of the unit 40U in the travel direction of the laser light. Therefore, the deterioration speed of at least the beam splitter 410B among the optical elements in the unit 10U is higher than the deterioration speed of the beam splitter 440B, which is an optical element of the unit 40U. Accordingly, when the unit 10U is the first unit and the unit 40U is the second unit, the deterioration speed of at least one optical element of the first unit is higher than the deterioration speed of an optical element of the second unit located on the opposite side of the opening 114h with respect to the first unit.

Further, as described above, the looped optical path 430L is located on the −H direction side with respect to the looped optical path 420L, and the looped optical path 420L and the looped optical path 430L overlap each other in a direction parallel to the H direction. Therefore, the unit 20U is located on the opening 114h side with respect to the unit 30U, and the unit 20U and the unit 30U overlap each other in a direction parallel to the opening direction of the opening 114h. The unit 20U is arranged upstream of the unit 30U in the travel direction of the laser light. Therefore, the deterioration speed of at least the beam splitter 420B among the optical elements in the unit 20U is higher than the deterioration speed of the beam splitter 430B, which is an optical element of the unit 30U. Accordingly, when the unit 20U is the first unit and the unit 30U is the second unit, the deterioration speed of at least one optical element of the first unit is higher than the deterioration speed of an optical element of the second unit located on the opposite side of the opening 114h with respect to the first unit.

The units 10U to 40U are held by the movement mechanisms 117a to 117d. Specifically, the units 10U, 40U are held by the movement mechanisms 117a, 117b, and the units 20U, 30U are held by the movement mechanisms 117c, 117d. The movement mechanisms 117a, 117b can move the units 10U, 40U to be taken in and out through the opening 114h. The movement mechanisms 117a, 117b are configured of, for example, a rail extending in a direction parallel to the H direction, and the movement direction of the units 10U, 40U being held is a direction parallel to the H direction, which is the horizontal direction. Each of the units 10U, 40U held by the movement mechanisms 117a, 117b is positioned in a direction parallel to the H direction by a positioning mechanism (not shown) configured by a pin, a V groove, or the like, and is fixed by a fixing mechanism (not shown) such as a bolt.

The movement mechanisms 117c, 117d can move the units 20U, 30U to be taken in and out through the opening 114h. Similarly to the movement mechanisms 117a, 117b, the movement mechanisms 117c, 117d are configured of, for example, a rail extending in a direction parallel to the H direction, and the movement direction of the units 20U, 30U being held is a direction parallel to the H direction, which is the horizontal direction. Each of the units 20U, 30U held by the movement mechanisms 117c, 117d is positioned in a direction parallel to the H direction by a positioning mechanism (not shown) configured by a pin, a V groove, or the like, and is fixed by a fixing mechanism (not shown) such as a bolt.

### 3.2 Maintenance Method of Pulse Stretcher

Next, a maintenance method of the pulse stretcher 400 of the first embodiment will be described.

In the present embodiment, the timing of maintenance is determined in advance for each of the units 10U to 40U. The timing is determined by, for example, the number of times the pulse laser light is output from the gas laser device 100. The processor 190 counts the number of times of output, and when there is a unit that reaches the number of times of output for maintenance, the processor 190 causes the display unit 180 to display the name of the unit. An operator performs maintenance of the displayed unit. The maintenance frequency of the unit 10U is higher than the maintenance frequency of the unit 40U, and the maintenance frequency of the unit 20U is higher than the maintenance frequency of the unit 30U.

In the present embodiment, the number of times of output when maintenance is to be performed is the same for the units 10U, 20U, and the number of times of output when maintenance is to be performed for the units 30U, 40U is twice the number of times of output when maintenance is to be performed for the units 10U, 20U. Therefore, maintenance of the units 10U, 20U is performed simultaneously, and maintenance of the units 30U, 40U is performed simultaneously. Further, maintenance of the units 10U, 20U is also performed when maintenance of the units 30U, 40U is performed.

Here, the timing of maintenance of the units 10U, 20U may be different, and the timing of maintenance of the units 30U, 40U may be different. Further, the timing of maintenance may be determined by a factor other than the number of times of output, and may be determined based on, for example, the operation time of the gas laser device 100.

First, maintenance of the units 10U, 20U will be described. The operator stops the operation of the gas laser device 100 and removes the maintenance panel 116 from the second main body portion 112. Next, the fixing mechanism fixing the unit 10U is released, the unit 10U is taken out from the second main body portion 112 through the opening 114h using the movement mechanisms 117a, 117b, and the optical elements of the unit 10U are replaced. Here, some of the optical elements of the unit 10U may be replaced, or all optical elements may be replaced. Alternatively, the unit 10U taken out may be replaced with a new unit 10U. Further, similarly to the unit 10U, the unit 20U is taken out and replacement of the optical elements of the unit 20U or the replacement of the unit 20U is performed. Next, the unit 10U is accommodated in an accommodation space of the second main body portion 112 through the opening 114h using the movement mechanisms 117a, 117b, positioned by the positioning mechanism, and fixed by the fixing mechanism. Then, the unit 20U is accommodated in an accommodation space of the second main body portion 112, positioned by the positioning mechanism, and fixed by the fixing mechanism. Next, after the maintenance panel 116 is attached to the second main body portion 112 to close the opening 114h, the gas laser device 100 is operated. Here, since the unit 10U and the unit 20U can be taken out and accommodated separately, the order of taking out and accommodating the unit 10U and the unit 20U need not be as described above.

Next, maintenance of the units 30U, 40U will be described. Similarly to maintenance of the units 10U, 20U, the operator stops the operation of the gas laser device 100 and removes the maintenance panel 116 from the second main body portion 112. Then, the unit 10U is taken out from the second main body portion 112 through the opening 114h. Next, the fixing mechanism fixing the unit 10U is released, and the unit 40U is taken out from the second main body portion 112 through the opening 114h using the movement mechanisms 117a, 117b, Further, with respect to the units 20U, 30U, similarly to the units 10U, 40U, after the unit 20U is taken out from the second main body portion 112, the unit 30U is taken out from the second main body portion 112.

Next, the optical elements of the taken-out unit 40U are replaced or the unit 40U is replaced. Further, the optical elements of the taken-out unit 30U are replaced or the unit 30U is replaced. Then, the units 30U, 40U are accommodated in an accommodation space of the second main body portion 112, positioned by the positioning mechanism, and fixed by the fixing mechanism.

As described above, the number of times of output when maintenance is to be performed for the units 30U, 40U is twice the number of times of output when maintenance is to be performed for the units 10U, 20U. Therefore, the optical elements of the taken-out units 10U, 20U are replaced or the units 10U, 20U are replaced. Then, the units 10U, 20U are accommodated in the accommodation space of the second main body portion 112, positioned by the positioning mechanism, and fixed by the fixing mechanism. Here, when maintenance of the units 10U, 20U is not performed at the timing of maintenance of the units 30U, 40U, the taken-out units 10U, 20 are accommodated and fixed in the accommodation space of the second main body portion 112 without replacement.

After the units 10U, 20U, 30U, 40U are accommodated and fixed in the accommodation space of the second main body portion 112 in this manner, the maintenance panel 116 is attached to the second main body portion 112 to close the opening 114h, and the gas laser device 100 is operated.

### 3.3 Effect

In the pulse stretcher 400 of the present embodiment, each of the units 10U to 40U includes two or more optical elements including at least one of the beam splitter and the mirror, and can be individually taken in and out through the opening 114h of the second main body portion 112 of the housing 110. Therefore, at the time of maintenance, since two or more optical elements can be taken out at a time, it is possible to facilitate taking out the optical elements as compared with a case in which the optical elements are taken out from the second main body portion 112 one by one. Further, the deterioration speed of at least one optical element of the unit 10U is higher than the deterioration speed of the optical elements of the unit 40U located on the opposite side of the opening 114h with respect to the unit 10U. Therefore, the unit 10U including the optical elements that tend to have high replacement frequency can be easily accessed than when the unit 40U is located on the opening 114h side with respect to the unit 10U. Further, the deterioration speed of at least one optical element of the unit 20U is higher than the deterioration speed of the optical elements of the unit 30U located on the opposite side of the opening 114h with respect to the unit 20U. Therefore, the unit 20U including the optical elements that tend to have high replacement frequency can be easily accessed than when the unit 30U is located on the opening 114h side with respect to the unit 20U. Therefore, according to the gas laser device 100 of the present embodiment, replacement of optical elements having a high replacement frequency can be facilitated, and maintenance can be facilitated.

In the pulse stretcher 400 of the present embodiment, the unit 10U and the unit 40U overlap each other and the unit 20U and the unit 30U overlap each other in a direction parallel to the opening direction of the opening 114h. Therefore, it is possible to prevent the pulse stretcher 400 from becoming larger in a direction perpendicular to the opening direction of the opening 114h. In a direction parallel to the opening direction of the opening 114h, the unit 10U and the unit 40U may not overlap each other, and the unit 20U and the unit 30U may not overlap each other.

In the pulse stretcher 400 of the present embodiment, the units 10U to 40U are formed respectively for the looped optical paths 410L to 440. Therefore, it is possible to facilitate maintenance of each looped optical path 410L to 440L.

In the pulse stretcher 400 of the present embodiment, the optical elements of the unit 40U are arranged downstream of the optical elements of the unit 10U in the travel direction of the pulse laser light, and the number of optical elements of the unit 10U is smaller than the number of optical elements of the unit 40U. Therefore, the pulse width may be extended before the laser light travels to the unit 40U in which the number of optical elements is large, and the deterioration speed of the optical elements of the unit 40U may be lowered. Therefore, it is possible to reduce the frequency of maintenance of the unit 40U in which the number of optical elements is large, and it is possible to suppress an increase in cost of maintenance. Here, the number of optical elements of the unit 10U may be equal to or larger than the number of optical elements of the unit 40U.

In the gas laser device 100 of the present embodiment, the second main body portion 112 of the housing 110 includes the movement mechanisms 117a to 117d that move the units 10U to 40U so as to be able to be taken in and out through the opening 114h. Therefore, the units 10U to 40U can be easily taken in and out. Here, the second main body portion 112 may not include the movement mechanisms 117a to 117d.

In the gas laser device 100 of the present embodiment, the movement direction of the units 10U to 40U by the movement mechanisms 117a to 117d is the horizontal direction. Therefore, when the units 10U to 40U are taken in and out, unintentional movement of the units 10U to 40U due to its own weight can be suppressed. Here, the movement direction of the units 10U to 40U by the movement mechanisms 117a to 117d may be non-parallel to the horizontal direction.

The pulse stretcher 400 of the present embodiment further includes the light guide optical system 401 which includes the two light guide mirrors 402, 403 and causes the pulse laser light to be sequentially incident on the beam splitters 410B to 440B of the four looped optical paths 410L to 440L. Therefore, the degree of freedom in arrangement of the four looped optical paths 410L to 440L is improved as compared with a case in which the light guide optical system 401 is not included.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

The pulse stretcher 400 of the present embodiment is mainly different from the pulse stretcher 400 of the comparative example in that six units are configured.

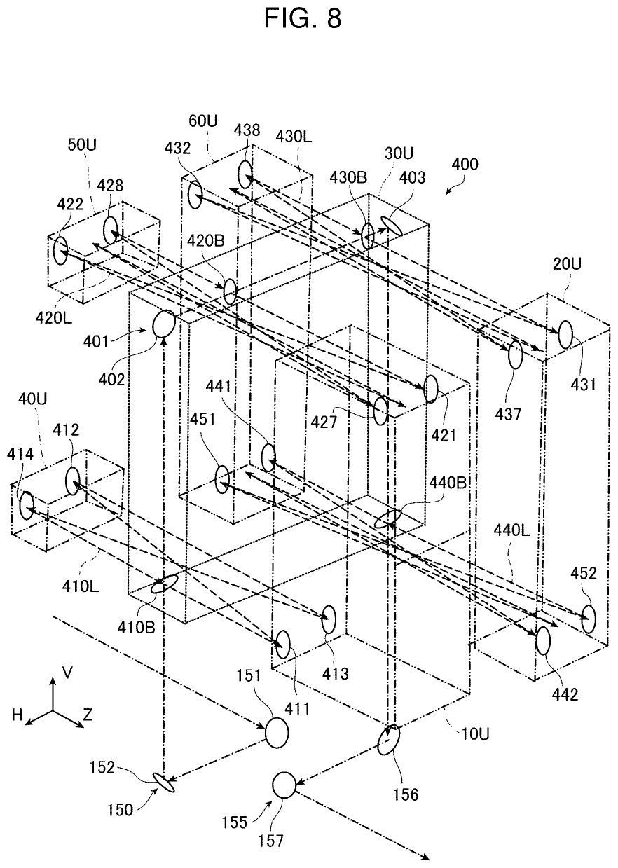

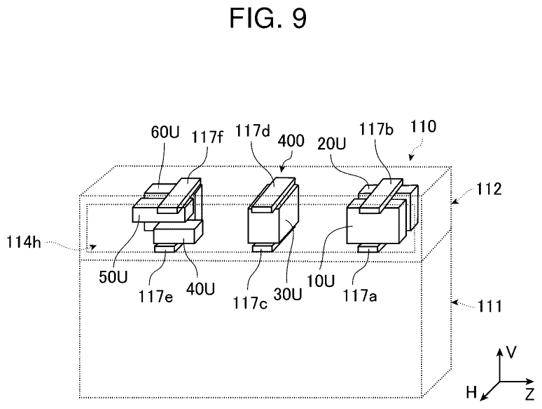

FIG. 8 is a schematic view of a schematic configuration example of the first light guide unit 150, the second light guide unit 155, and the pulse stretcher 400 of the present embodiment viewed obliquely from above. FIG. 9 is a schematic view showing the plurality of units and the housing 110 of the present embodiment in a similar manner as in FIG. 6. As shown in FIGS. 8 and 9, the pulse stretcher 400 of the present embodiment includes six units 10U, 20U, 30U, 40U, 50U, 60U. The units 10U to 60U can be individually taken in and out through the opening 114h of the second main body portion 112. Further, the second main body portion 112 of the present embodiment includes six movement mechanisms 117a to 117f.

The unit 10U includes the circulation mirrors 411, 413, which are optical elements configuring a part of the looped optical path 410L, the circulation mirrors 421, 423, 425, 427 which are optical elements configuring a part of the looped optical path 420L, and a frame (not shown) as a main configuration. Therefore, the number of optical elements included in the unit 10U is six. The circulation mirrors 411, 413, 421, 423, 425, 427 are located on the Z direction side with respect to the light guide mirrors 402, 403. The circulation mirrors 411, 413, 421, 423, 425, 427 are supported by the frame with the inclination angles thereof adjusted.

The unit 20U includes the circulation mirrors 431, 433, 435, 437, which are optical elements configuring a part of the looped optical path 430L, the circulation mirrors 442, 444, 446, 448, 450, 452 which are optical elements configuring a part of the looped optical path 440L, and a frame (not shown) as a main configuration. Therefore, the number of optical elements included in the unit 20U is ten. The circulation mirrors 431, 433, 435, 437, 442, 444, 446, 448, 450, 452 are located on the Z direction side with respect to the light guide mirrors 402, 403. The circulation mirrors 431, 433, 435, 437, 442, 444, 446, 448, 450, 452 are supported by the frame with the inclination angles thereof adjusted.

The unit 30U includes the beam splitters 410B to 440B in the looped optical paths 410L to 440L, the light guide mirrors 402, 403, and a frame (not shown) as a main configuration. Therefore, the number of optical elements included in the unit 30U is six. The beam splitters 410B to 440B and the light guide mirrors 402, 403 are supported by the frame with the inclination angles thereof adjusted. When a unit including all beam splitters and all light guide mirrors is defined as a third unit, the unit 30U is the third unit.

The unit 40U includes the circulation mirrors 412, 414, which are optical elements configuring another part of the looped optical path 410L, and a frame (not shown) as a main configuration. Therefore, the number of optical elements included in the unit 40U is two. The circulation mirrors 412, 414 are located on the −Z direction side with respect to the light guide mirrors 402, 403. The circulation mirrors 412, 414 are supported by the frame with the inclination angles thereof adjusted.

The unit 50U includes the circulation mirrors 422, 424, 426, 428, which are optical elements configuring another part of the looped optical path 420L, and a frame (not shown) as a main configuration. Therefore, the number of optical elements included in the unit 50U is four. The circulation mirrors 422, 424, 426, 428 are located on the −Z direction side with respect to the light guide mirrors 402, 403. The circulation mirrors 422, 424, 426, 428 are supported by the frame with the inclination angles thereof adjusted.

The unit 60U includes the circulation mirrors 432, 434, 436, 438, which are optical elements configuring another part of the looped optical path 430L, the circulation mirrors 441, 443, 445, 447, 449, 451, which are optical elements configuring another part of the looped optical path 440L, and a frame (not shown) as a main configuration. Therefore, the number of optical elements included in the unit 60U is ten. The circulation mirrors 432, 434, 436, 438, 441, 443, 445, 447, 449, 451 are located on the −Z direction side with respect to the light guide mirrors 402, 403. The circulation mirrors 432, 434, 436, 438, 441, 443, 445, 447, 449, 451 are supported by the frame with the inclination angles thereof adjusted.

In the present embodiment, the unit 10U is located on the opening 114h side with respect to the unit 20U, and the unit 10U and the unit 20U overlap each other in a direction parallel to the opening direction of the opening 114h. Further, the looped optical paths 430L, 440L are arranged downstream of the looped optical paths 410L, 420L in the travel direction of the laser light. Therefore, the deterioration speed of the circulation mirrors 411, 413, 421, 423, 425, 427, which are all optical elements of the unit 10U, is higher than the deterioration speed of the circulation mirrors 431, 433, 435, 437, 442, 444, 446, 448, 450, 452, which are all optical elements of the unit 20U. Accordingly, when the unit 10U is the first unit and the unit 20U is the second unit, the deterioration speed of at least one optical element of the first unit is higher than the deterioration speed of an optical element of the second unit located on the opposite side of the opening 114h with respect to the first unit.

Further, the units 40U, 50U are located on the opening 114h side with respect to the unit 60U, and the units 40U, 50U and the unit 60U overlap each other in a direction parallel to the opening direction of the opening 114h. Further, the looped optical paths 430L, 440L are arranged downstream of the looped optical paths 410L, 420L in the travel direction of the laser light. Therefore, the deterioration speed of the circulation mirrors 412, 414, which are all optical elements of the unit 40U, and the circulation mirrors 422, 424, 426, 428, which are all optical elements of the unit 50U, is higher than the deterioration speed of the circulation mirrors 432, 434, 436, 438, 441, 443, 445, 447, 449, 451, which are all optical elements of the unit 60U. Accordingly, when the units 40U, 50U are the first unit and the unit 60U is the second unit, the deterioration speed of at least one optical element of the first unit is higher than the deterioration speed of an optical element of the second unit located on the opposite side of the opening 114h with respect to the first unit.

The units 10U to 60U are held by the movement mechanisms 117a to 117f. Specifically, the units 10U, 20U are held by the movement mechanisms 117a, 117b. The unit 30U is held by the movement mechanisms 117c, 117d. The unit 40U is held by the movement mechanism 117e. The unit 50U is held by the movement mechanism 117f. The unit 60U is held by the movement mechanisms 117e, 117f. The movement mechanisms 117a, 117b can move the units 10U, 20U to be taken in and out through the opening 114h. The movement mechanisms 117c, 117d can move the unit 30U to be taken in and out through the opening 114h. The movement mechanism 117e can move the unit 40U to be taken in and out through the opening 114h, and the movement mechanism 117f can move the unit 50U to be taken in and out through the opening 114h. Further, the movement mechanisms 117e, 117f can move the unit 60U to be taken in and out through the opening 114h. Similarly to the movement mechanisms 117a to 117d of the first embodiment, the movement mechanisms 117a to 117f are configured of, for example, a rail extending in a direction parallel to the H direction, and the movement direction of the units 10U to 60U is the horizontal direction. Further, similarly to the units 10U to 40U of the first embodiment, the units 10U to 60U are positioned in a direction parallel to the H direction by a positioning mechanism (not shown) configured by a pin, a V groove, or the like, and are fixed by a fixing mechanism (not shown) such as a bolt.

### 4.2 Maintenance Method of Pulse Stretcher

Next, a maintenance method of the pulse stretcher 400 of the second embodiment will be described.

In the present embodiment, similarly to the first embodiment, the timing of maintenance is determined in advance for each of the units 10U to 60U, and the timing is determined by the number of times of output of the pulse laser light. The maintenance frequency of the unit 10U is higher than the maintenance frequency of the unit 20U, and the maintenance frequency of the units 40U, 50U is higher than the maintenance frequency of the unit 60U.

In the present embodiment, the number of times of output when maintenance is to be performed is the same for the units 10U, 30U, 40U, 50U, and the number of times of output when maintenance is to be performed for the units 20U, 60U is twice the number of times of output when maintenance is to be performed for the units 10U, 30U, 40U, 50U. Therefore, maintenance of the units 10U, 30U, 40U, 50U is performed simultaneously, and maintenance of the units 20U, 60U is performed simultaneously. Further, maintenance of the units 10U, 30U, 40U, 50U is also performed when maintenance of the units 20U, 60U is performed.

First, maintenance of the units 10U, 30U, 40U, 50U will be described. Similarly to maintenance of the units 10U, 20U of the first embodiment, the operator stops the operation of the gas laser device 100 and removes the maintenance panel 116 from the second main body portion 112. Next, the fixing mechanism fixing the units 10U, 30U, 40U, 50U is released. The units 10U, 30U, 40U, 50U are taken out from the second main body portion 112 through the opening 114h using the movement mechanisms 117a to 117f, and the optical elements of the units 10U, 30U, 40U, 50U are replaced. Here, some of the optical elements of the units 10U, 30U, 40U, 50U may be replaced, or all optical elements may be replaced. Alternatively, the taken-out units 10U, 30U, 40U, 50U may be replaced with new units 10U, 30U, 40U, 50U. Next, the units 10U, 30U, 40U, 50U are accommodated in the accommodation space of the second main body portion 112 through the opening 114h using the movement mechanisms 117a to 117f, positioned by the positioning mechanism, and fixed by the fixing mechanism. After the opening 114h is closed by the maintenance panel 116, the gas laser device 100 is operated.

Next, maintenance of the units 20U, 60U will be described. Similarly to maintenance of the units 10U, 30U, 40U, 50U, the operator stops the operation of the gas laser device 100 and removes the maintenance panel 116 from the second main body portion 112. Then, as described above, the units 10U, 30U, 40U, 50U are taken out from the second main body portion 112. Next, the fixing mechanism fixing the units 20U, 60U is released, and the units 20U, 60U are taken out from the second main body portion 112 through the opening 114h using the movement mechanisms 117a, 117b, 117e, 117f, The optical elements of the taken-out units 20U, 60U are replaced or the units 20U, 60U are replaced. Then, the units 20U, 60U are accommodated in the accommodation space of the second main body portion 112, positioned by the positioning mechanism, and fixed by the fixing mechanism.

In the present embodiment, replacement of the optical elements of the units 10U, 30U, 40U, 50U or replacement of the units 10U, 30U, 40U, 50U are performed, and the units 10U, 30U, 40U, 50U are accommodated and fixed in the accommodation space of the second main body portion 112. When maintenance of the units 10U, 30U, 40U, 50U is not performed at the timing of maintenance of the units 20U, 60U, the taken-out units 10U, 30U, 40U, 50U are accommodated and fixed in the accommodation space of the second main body portion 112 without replacement.

After the units 10U to 60U are accommodated and fixed in the accommodation space of the second main body portion 112 in this manner, the maintenance panel 116 is attached to the second main body portion 112 to close the opening 114h, and the gas laser device 100 is operated.

### 4.3 Effect

In the looped optical path, the beam splitter repeats reflection and transmission of the pulse laser light many times, and thus the deterioration speed is higher than that of the mirror. In the pulse stretcher 400 of the present embodiment, the unit 30U includes all beam splitters 410B to 440B. Therefore, the plurality of beam splitters 410B to 440B having such a high deterioration speed can be simultaneously replaced. Here, from the viewpoint of simultaneously replacing the plurality of beam splitters, it is simply required that the unit 30U includes a plurality of beam splitters. For example, the unit 30U may not include some beam splitters.

In the pulse stretcher 400 of the present embodiment, the unit 30U includes all light guide mirrors 402, 403. Therefore, maintenance of the beam splitters 410B to 440B and maintenance of the light guide optical system 401 can be performed simultaneously. Here, the unit 30U may not include at least one of the light guide mirrors 402, 403.

### 4.4 Description of First Modification

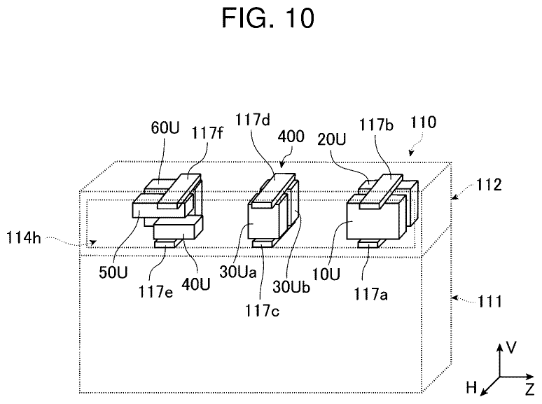

Next, the gas laser device 100 of a first modification of the second embodiment will be described. FIG. 10 is a schematic view showing the plurality of units and the housing 110 of the present modification in a similar manner as in FIG. 6. As shown in FIG. 10, the pulse stretcher 400 of the present modification is mainly different from the pulse stretcher 400 of the second embodiment in that the unit 30U is divided into two units 30Ua, 30Ub.

The unit 30Ua includes the beam splitters 410B, 420B in the looped optical paths 410L, 420L, the light guide mirror 402, and a frame (not shown) as a main configuration. The beam splitters 410B, 420B and the light guide mirror 402 are located on the H direction side with respect to the optical axis of the laser light transmitted through the output coupling mirror 370. The beam splitters 410B, 420B and the light guide mirror 402 are supported by the frame with the inclination angles thereof adjusted.

The unit 30Ub includes the beam splitters 430B, 440B in the looped optical paths 430L, 440L, the light guide mirror 403, and a frame (not shown) as a main configuration. The beam splitters 430B, 440B and the light guide mirror 403 are located on the −H direction side with respect to the optical axis of the laser light transmitted through the output coupling mirror 370. The beam splitters 430B, 440B and the light guide mirror 403 are supported by the frame with the inclination angles thereof adjusted. Here, when a unit including a plurality of beam splitters is defined as a third unit, the units 30Ua, 30Ub are the third unit.

In the present modification, the unit 30Ua is located on the opening 114h side with respect to the unit 30Ub, and the unit 30Ua and the unit 30Ub overlap each other in a direction parallel to the opening direction of the opening 114h. Further, the looped optical paths 430L, 440L are arranged downstream of the looped optical paths 410L, 420L in the travel direction of the laser light. Therefore, the deterioration speed of the beam splitters 410B, 420B, which are the optical elements of the unit 30Ua, is higher than the deterioration speed of the beam splitters 430B, 440B, which are optical elements of the unit 30Ub. Accordingly, when the unit 30Ua is the first unit and the unit 30Ub is the second unit, the deterioration speed of at least one optical element of the first unit is higher than the deterioration speed of an optical element of the second unit located on the opposite side of the opening 114h with respect to the first unit.

In the present modification, maintenance of the unit 30Ua is performed together with maintenance of the units 10U, 40U, 50U, and maintenance of the units 30Ua, 30Ub is performed together with maintenance of the units 10U, 20U, 40U, 50U, 60U.

According to the gas laser device 100 of the present modification, the unit 30Ua including the optical elements that tend to have high replacement frequency can be easily accessed than when the unit 30Ub is located on the opening 114h side with respect to the unit 30Ua.

### 4.5 Description of Second Modification

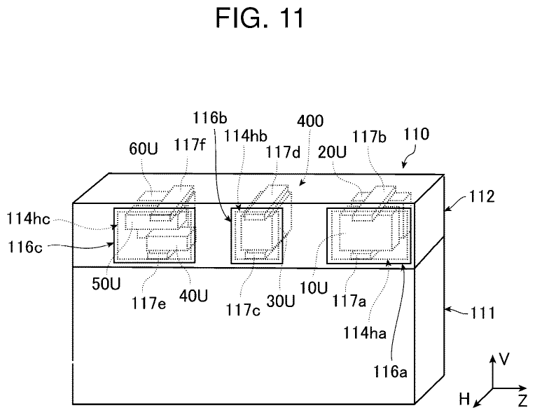

Next, the gas laser device 100 of a second modification of the second embodiment will be described. FIG. 11 is a schematic view showing the plurality of units and the housing 110 of the present modification. As shown in FIG. 11, the gas laser device 100 of the present modification is mainly different from the gas laser device 100 of the second embodiment in that three openings 114ha, 114hb, 114hc are formed in the second main body portion 112 and the housing 110 includes three maintenance panels 116a, 116b, 116c.

In the present modification, the units 10U, 20U overlap the opening 114ha in a direction parallel to the H direction, and can be taken in and out through the opening 114ha. The unit 30U overlaps the opening 114hb in a direction parallel to the H direction, and can be taken in and out through the opening 114hb. The units 40U, 50U and the unit 60U overlap the opening 114hc in a direction parallel to the H direction, and can be taken in and out through the opening 114hc.

The maintenance panel 116a is a plate-like member which closes the opening 114ha, the maintenance panel 116b is a plate-like member which closes the opening 114hb, and the maintenance panel 116c is a plate-like member which closes the opening 114hc. The maintenance panels 116a, 116b, 116c are detachably attached to the second main body portion 112.

According to the gas laser device 100 of the present modification, compared with a case in which the units 10U to 60U are taken in and out through one opening during maintenance, the accommodation space of the second main body portion 112 exposed to the outside can be made smaller and dust, dirt, and the like can be less likely to enter the accommodation space.

Although the above embodiments have been described as examples, the present disclosure is not limited thereto, and can be modified as appropriate.

In the first embodiment described above, the pulse stretcher 400 including four units 10U to 40U has been exemplified. However, it is only required that the pulse stretcher 400 includes a plurality of units each including two or more optical elements including at least one of a beam splitter and a mirror and being able to be individually taken in and out through the opening 114h, that the plurality of units include the first unit and the second unit located on the opposite side of the opening 114h with respect to the first unit, and that the deterioration speed of at least one optical element of the first unit is higher than the deterioration speed of the optical elements of the second unit. For example, in the pulse stretcher 400 of the first embodiment, the first unit configured of the units 10U, 20U and the second unit configured of the units 30U, 40U may be formed.

Further, in the above embodiments, the pulse stretcher 400 including four looped optical paths 410L to 440L has been exemplified. However, the number of the looped optical paths is only required to be plural.

Further, in the above embodiments, the looped optical path 410L in which the number of the circulation mirrors is four, the looped optical path 420L in which the number of the circulation mirrors is eight, the looped optical path 430L in which the number of the circulation mirrors is eight, and the looped optical path 440L in which the number of the circulation mirrors is twelve have been exemplified. However, the number of the circulation mirrors configuring each looped optical path is not limited. Here, it is preferable that the looped optical path arranged on the more downstream side in the travel direction of the pulse laser light has a larger number of circulation mirrors.

Further, in the above embodiments, the light guide optical system 401 configured of the two light guide mirrors 402, 403 has been exemplified. However, the number of the light guide mirrors configuring the light guide optical system 401 is not limited. Further, the pulse stretcher 400 may not include the light guide optical system 401.

Further, in the above embodiments, the first light guide unit 150 including the high reflection mirrors 151, 152 and the second light guide unit 155 including the two high reflection mirrors 156, 157 have been exemplified. However, as long as the laser light output from the chamber device CH3 enters the pulse stretcher 400, the number of high reflection mirrors included in each of the first light guide unit 150 and the second light guide unit 155 is not limited. Further, the gas laser device 100 may not include at least one of the first light guide unit 150 and the second light guide unit 155.

Further, in the above embodiments, the housing 110 including the first main body portion 111 and the second main body portion 112 arranged on the upper wall of the first main body portion 111 has been exemplified. However, the arrangement of the second main body portion 112 is not limited. For example, the second main body portion 112 may be arranged below the first main body portion 111. The first main body portion 111 may also serve as the second main body portion 112. That is, the pulse stretcher 400 may be arranged in the accommodation space of the first main body portion 111. Further, the opening direction of the opening 114h is not limited. For example, the opening 114h may be formed in the upper wall 115 of the second main body portion 112.

Further, in the above embodiments, the beam splitters 410B to 440B causing the laser light reflected thereby to propagate to the looped optical paths 410L to 440L respectively have been exemplified. However, the laser light transmitted through the beam splitters 410B to 440B may propagate to the looped optical paths 410L to 440L. In this case, the beam splitters 410B to 440B serve as a part of the light guide optical system 401, and the beam splitters 410B to 440B serve for both the light guide optical system 401 and the looped optical paths 440L to 440L.

In the above embodiments, the gas laser device 100 including the laser oscillator 130 and the amplifier 160 have been exemplified. However, the gas laser device 100 may not include the amplifier 160. In this case, for example, the laser light output from the chamber device CH1 and transmitted through the output coupling mirror 70 enters the pulse stretcher 400.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device configured to output pulse laser light;
a pulse stretcher including a plurality of looped optical paths through which a pulse width of the pulse laser light is extended; and
a housing including a main body portion in which the pulse stretcher is accommodated and an opening through which the pulse stretcher can be taken in and out is formed,
each of the looped optical paths including a beam splitter on which the pulse laser light is incident, and a plurality of circulation mirrors configured to sequentially reflect a part of the pulse laser light incident on the beam splitter and return the part of the pulse laser light to the beam splitter so as to be superimposed on another part of the pulse laser light,
the pulse stretcher including a plurality of units each including two or more optical elements including at least one of the beam splitter and the circulation mirrors, and each being able to be individually taken in and out through the opening,
the plurality of units including a first unit and a second unit located on an opposite side of the opening with respect to the first unit, and
a deterioration speed of at least one of the optical elements of the first unit being higher than a deterioration speed of the optical elements of the second unit.

2. The gas laser device according to claim 1,
wherein the first unit and the second unit overlap each other in a direction parallel to an opening direction of the opening.

3. The gas laser device according to claim 1,
wherein the optical elements of the second unit are arranged downstream of the optical elements of the first unit in a travel direction of the pulse laser light.

4. The gas laser device according to claim 3,
wherein a number of the optical elements of the first unit is smaller than a number of the optical elements of the second unit.

5. The gas laser device according to claim 1,
wherein the housing further includes a movement mechanism that moves the units so as to be able to be taken in and out through the opening.

6. The gas laser device according to claim 5,
wherein a movement direction of the units by the movement mechanism is the horizontal direction.

7. The gas laser device according to claim 1,
wherein the circulation mirrors are concave mirrors.

8. The gas laser device according to claim 1,
wherein at least one of the units includes the beam splitter and the circulation mirror.

9. The gas laser device according to claim 8,
wherein the units are formed respectively for the looped optical paths.

10. The gas laser device according to claim 1,
wherein the plurality of units include a third unit including a plurality of the beam splitters.

11. The gas laser device according to claim 10,
wherein the third unit includes all the beam splitters.

12. The gas laser device according to claim 1,
wherein the pulse stretcher further includes a light guide optical system which includes a plurality of light guide mirrors that are the optical elements other than the beam splitter and the circulation mirrors, and which causes the pulse laser light to be sequentially incident on the beam splitters of the plurality of looped optical paths.

13. The gas laser device according to claim 12,
wherein the plurality of units include a third unit including at least one of the light guide mirrors.

14. The gas laser device according to claim 13,
wherein the third unit includes all the light guide mirrors.

15. An electronic device manufacturing method, comprising:
outputting pulse laser light generated by a gas laser device to an exposure apparatus; and
exposing a photosensitive substrate in the exposure apparatus to the pulse laser light output to the exposure apparatus to manufacture an electronic device,
the gas laser device including:
a chamber device configured to output the pulse laser light;
a pulse stretcher including a plurality of looped optical paths through which a pulse width of the pulse laser light is extended; and
a housing including a main body portion in which the pulse stretcher is accommodated and an opening through which the pulse stretcher can be taken in and out is formed,
each of the looped optical paths including a beam splitter on which the pulse laser light is incident, and a plurality of circulation mirrors configured to sequentially reflect a part of the pulse laser light incident on the beam splitter and return the part of the pulse laser light to the beam splitter so as to be superimposed on another part of the pulse laser light,
the pulse stretcher including a plurality of units each including two or more optical elements including at least one of the beam splitter and the circulation mirrors, and each being able to be individually taken in and out through the opening,
the plurality of units including a first unit and a second unit located on an opposite side of the opening with respect to the first unit, and
a deterioration speed of at least one of the optical elements of the first unit being higher than a deterioration speed of the optical elements of the second unit.
